(19) United States
(12) Patent Application Publication
(10) Pub. No.: US 2025/0236947 A1
(43) Pub. Date: Jul. 24, 2025

(54) Dielectric Deposition Ring with Fins for Physical Vapor Deposition

(71) Applicant: Applied Materials, Inc., Santa Clara, CA (US)

(72) Inventors: Ming-Jui LI, Sunnyvale, CA (US); Wen XIAO, San Jose, CA (US); Harish Varma PENMETHSA, Dublin, CA (US); Brijesh RAJU, Fremont, CA (US); Puviyarasu PALANISAMY, Bangalore (IN); Vasu Reddy CHINTALA, Mountain View, CA (US); Alejandro LIZARRAGA MALDONADO, San Jose, CA (US); Michelle TJAKRADINATA, San Jose, CA (US); Srinivasa Rao YEDLA, Bangalore (IN)

(21) Appl. No.: 18/417,160

(22) Filed: Jan. 19, 2024

(51) Int. Cl. C23C 14/50

(52) U.S. Cl. CPC C23C 14/50

(57) ABSTRACT

Methods and apparatus for processing a substrate are provided herein. In some embodiments, a process kit for a substrate support includes: a dielectric plate having a lower surface configured to cover a support surface of the substrate support and an upper surface configured to support a substrate; and a dielectric deposition ring surrounding the dielectric plate and configured to cover a portion of the substrate support disposed radially outward of the support surface.

### FIELD

Embodiments of the present disclosure generally relate to semiconductor processing apparatus and processing.

### BACKGROUND

The inventors have observed arcing defects in some high-power physical vapor deposition (PVD) processes depositing metal on warped substrates.

Specifically, the inventors have observed that warped substrates have arcing defects when substrate edges create a gap between the substrate and a grounded substrate support. The gap allows for metal deposition on the substrate support and induces arcing when the substrate is shorted with the substrate support.

Accordingly, the inventors have provided embodiments of improved apparatus and techniques for processing a substrate.

### SUMMARY

Methods and apparatus for processing a substrate are provided herein. In some embodiments, a process kit for a substrate support includes: a dielectric plate having a lower surface configured to cover a support surface of the substrate support and an upper surface configured to support a substrate; and a dielectric deposition ring surrounding the dielectric plate and configured to cover a portion of the substrate support disposed radially outward of the support surface.

In some embodiments, apparatus for processing a substrate includes: a substrate support having a support surface and an outer ledge disposed outward of the support surface, wherein the support surface is elevated with respect to the outer ledge; and a process kit disposed atop the substrate support. The process kit can include: a dielectric plate having a lower surface covering the support surface and an upper surface configured to support a substrate; and a dielectric deposition ring surrounding the dielectric plate and covering the outer ledge.

In some embodiments, a physical vapor deposition chamber includes: chamber body; a lid assembly coupled to the chamber body and configured to support one or more targets for depositing one or more materials onto a substrate during use; a substrate support disposed within the chamber body opposite the lid assembly, the substrate support having a support surface and an outer ledge disposed outward of the support surface, wherein the support surface is elevated with respect to the outer ledge; and a process kit disposed atop the substrate support, the process kit including: a dielectric plate having a lower surface covering the support surface and an upper surface configured to support a substrate; and a dielectric deposition ring surrounding the dielectric plate and covering the outer ledge.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a schematic diagram of a physical vapor deposition system having a process kit in accordance with embodiments of the present disclosure.

FIG. 2 is a schematic side view of a portion of a substrate support and process kit in accordance with embodiments of the present disclosure.

FIG. 3 is a schematic side view of a portion of a substrate support and process kit in accordance with embodiments of the present disclosure.

FIG. 4 is a schematic side view of a portion of a substrate support and process kit in accordance with embodiments of the present disclosure.

FIG. 5 is a schematic side view of a portion of a substrate support and process kit in accordance with embodiments of the present disclosure.

FIG. 6 is a schematic side view of a portion of a substrate support and process kit in accordance with embodiments of the present disclosure.

FIG. 7 is a schematic side view of a portion of a substrate support and process kit in accordance with embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and apparatus for processing a substrate are provided herein.

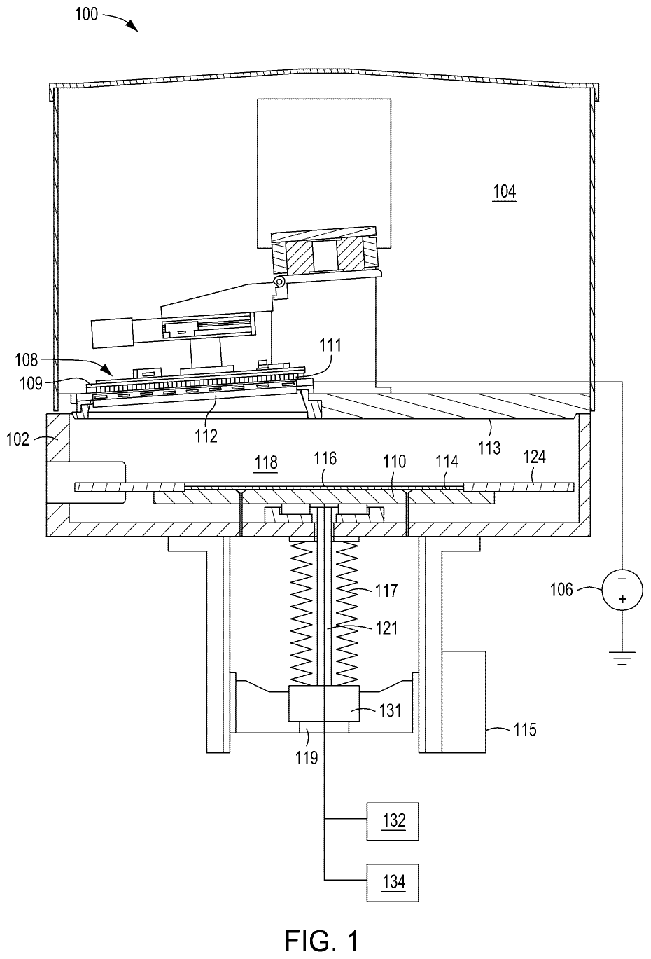

FIG. 1 is a side cross-sectional view of a PVD chamber 100 that may be used in the substrate processing system of FIG. 1, according to certain embodiments. In some embodiments, the PVD chamber 100 may be a deposition chamber that is part of a multi-chamber substrate processing system. In some embodiments, the PVD chamber 100 may be a standalone deposition chamber. Although particular details of a PVD chamber is described with respect to FIG. 1, other PVD chambers can also be suitably modified in accordance with the teachings disclosed herein.

The PVD chamber 100 generally includes a chamber body 102, a lid assembly 104 coupled to the chamber body 102, a magnetron 108 coupled to the lid assembly 104, a substrate support 110 disposed within the chamber body 102, and one or more targets 112 disposed between the magnetron 108 and the substrate support 110. Although one target 112 is shown in FIG. 1, a plurality of targets 112 can be provided in the PVD chamber 100. For example, other embodiments of PVD chambers suitable for modification in accordance with the teachings disclosed herein are described in commonly owned United States patent application publication number 2023/0130947 A1, published Apr. 27, 2023, and entitled “Tilted PVD Source with Rotating Pedestal.”

During processing, the interior of the PVD chamber 100, or processing region 118, is maintained at a vacuum pressure. The processing region 118 is generally defined by the chamber body 102 and the lid assembly 104, such that the processing region 118 is primarily disposed between the target 112 and the substrate supporting surface of the substrate support 110.

A power source 106 is electrically connected to the target 112 to apply a negatively biased voltage to the target 112. In certain embodiments, the power source 106 is either a straight DC mode source or a pulsed DC mode source. However, other types of power sources are also contemplated, such as radio frequency (RF) sources.

The target 112 includes a target material and a backing plate, and is part of the lid assembly 104. A front surface of the target material of the target 112 defines a portion of the processing region 118. The backing plate is disposed between the magnetron 108 and target material of the target 112. The backing plate is electrically insulated from a support plate 113 of the lid assembly 104 by use of an electrical insulator to prevent an electrical short being created between the backing plate and the support plate 113 of the grounded lid assembly 104. In some embodiments, the backing plate may have one or more cooling channels configured to receive a coolant (e.g., DI water) therethrough to cool or control the temperature of the target 112.

The magnetron 108 is disposed over a portion of the target 112, and in a region of the lid assembly 104 that is maintained at atmospheric pressure. The magnetron 108 includes a plurality of magnets 111 attached to a shunt plate 109. The magnetron is used to confine a plasma proximate the target 112 to facilitate sputtering of material from the target 112 to be deposited on a substrate disposed on the substrate support 110 during processing.

The substrate support 110 has a support surface 114 to support a substrate 116. In some embodiments, the substrate support 110 may be configured to support the substrate by gravity, e.g., the substrate support does not include a vacuum chuck or electrostatic chuck. In some embodiments, the support surface 114 of the substrate support is conductive, such as made of metal.

A process kit 124, described below in more detail, is disposed over the support surface 114 and is used to support the substrate 116 and protect the substrate support 110 during processing. In some embodiments, the process kit 124 operates mechanically. For example, the weight of the process kit 124 may hold the process kit 124 in place on the substrate support. In some embodiments, the process kit 124 can be lifted by pins that are movable relative to the substrate support 110 to contact an underside of the process kit 124.

The temperature of the substrate 116 may be controlled using a temperature control system 132. In certain embodiments, the temperature control system 132 has an external cooling source that supplies coolant to the substrate support 110. In some embodiments, an RF bias source 134 is electrically coupled to the substrate support 110 to bias the substrate 116 during the sputtering process. Alternatively, the substrate support 110 may be grounded, floated, or biased with only a DC or RF voltage source. Biasing the substrate 116 can improve one or more of film density, adhesion, step coverage, and/or material reactivity on the substrate surface.

A shaft 121 is coupled to an underside of the substrate support 110. A rotary union 119 is coupled to a lower end of the shaft 121 to provide rotary fluid coupling with the temperature control system 132 and rotary electrical coupling with the RF bias source 134. The rotary union 119 includes a magnetic liquid rotary sealing mechanism (also referred to as a “Ferrofluidic® seal”) for vacuum rotary feedthrough.

In some embodiments, the substrate 116 is a panel. In some embodiments, the support surface 114 of the substrate support 110 fits a single square or rectangular panel substrate having sides of about 500 mm or greater, such as 510 mm by 515 mm or 600 mm by 600 mm. However, apparatus and methods of the present disclosure may be implemented with many different types and sizes of substrates, including circular wafers or rectangular panels having other dimensions.

In some embodiments, the substrate support 110 is rotatable about an axis perpendicular to at least a portion of the support surface 114 of the substrate support 110 (e.g., a vertical axis). In some embodiments, a motor 131 is provided to drive rotation of the substrate support 110 continuously in relation to the target 112 to improve film uniformity. A separate motor 115, for example, an electrically powered linear actuator, is provided to raise and lower the substrate support 110. A bellows 117 surrounds the shaft 121 and forms a seal between the chamber body 102 and the motor 131 during raising and lowering of the substrate support 110.

An underside surface of the target 112, which is defined by a surface of a target material, faces towards the support surface 114 of the substrate support 110 and towards a front side of the substrate 116. In some embodiments, the target material of the target 112 is formed from a metal for sputtering a corresponding film composition on the substrate 116. In one example, the target material may include a pure material or alloy containing elements selected from the group of copper (Cu), molybdenum (Mo), nickel (Ni), titanium (Ti), tantalum (Ta), aluminum (Al), cobalt (Co), gold (Au), silver (Ag), manganese (Mn), and silicon (Si). As examples, materials deposited on a substrate 116 may include pure metals, doped metals, metal alloys, metal nitrides, metal oxides, metal carbides containing these elements, as well as silicon containing oxides, nitrides, or carbides.

The inventors have discovered that, during processing, the substrate is sometimes warped and does not lie flat on the substrate support. In such situations, the inventors have further discovered that metal from the deposition process can deposit and accumulate on the backside of the substrate and/or on the substrate support surface, leading to arcing when the substrate is shorted to the substrate support. Additionally, the inventors have observed that the edge of the substrate needs to be sufficiently spaced from sharp edges to prevent the occurrence of bi-polar arcing. While electrostatic chucks or clamps might be used in other applications having warped substrates, the inventors have observed that such solutions cannot be used in certain applications, such as high power (e.g., above about 10 kWh) PVD deposition of metal materials on substrates having through-vias or other configurations where the metal materials can deposit directly on the substrate support, such as through the open via.

Typically, the backside of a substrate is in direct contact with the support surface 114 of the substrate support 110. For example, the entire backside of the substrate may be in electrical and thermal contact with the support surface of the substrate support, which can be made of metal. Accordingly, the inventors have provided substrate supports and process kits as described that advantageously reduce or overcome the above-described problems.

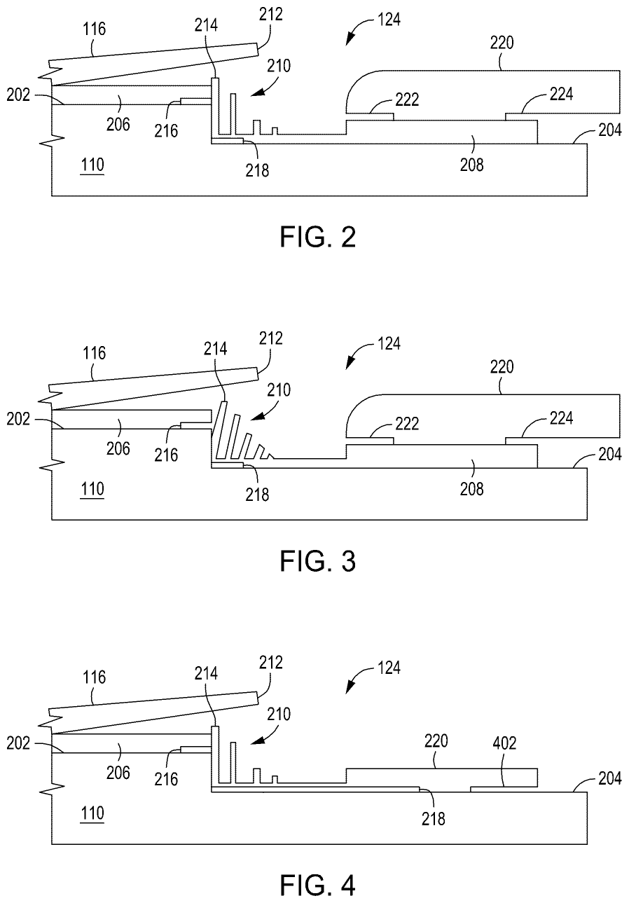

Although described in several illustrated embodiments in FIGS. 2-7, various aspects shown in any one figure can be combined or used in connection with embodiments described in any of the other figures. In one illustrative example, FIG. 2, depicts a schematic side view of a portion of a substrate support and process kit in accordance with embodiments of the present disclosure. The substrate support 110 includes a support surface 202 (e.g., support surface 114 in FIG. 1) and an outer ledge 204 disposed outward of the support surface 202. The support surface 202 is elevated with respect to the outer ledge 204. The support surface 202 has dimensions smaller than given dimensions of the substrate 116 to be supported, such that an outer edge 212 of the substrate 116 extends beyond the outer edge of the support surface 202. The support surface is substantially planar and can be held horizontally by the shaft 121 (e.g., see FIG. 1). The outer ledge 204 can also be substantially planar and disposed parallel to the support surface 202. A sidewall extends between the support surface 202 and the outer ledge 204. The sidewall can be substantially perpendicular to the support surface 202 and the outer ledge 204 (e.g., vertical). In some embodiments, the support surface 202 and the outer ledge 204 can be fabricated of metal to facilitate grounding and thermal control of the substrate 116 during processing.

The process kit 124 includes a dielectric plate 206 and a dielectric deposition ring 208. The dielectric plate 206 and the dielectric deposition ring 208 can be fabricated completely of a process compatible dielectric material or can be coated with such material at least along an upper surface thereof or on all process-volume exposed surfaces thereof (e.g., upper surface and sidewalls). Having the dielectric plate 206 and the dielectric deposition ring 208 fabricated completely of a dielectric material, or by coating the dielectric plate 206 and the dielectric deposition ring 208 with a dielectric material advantageously reduces the risk of shorting the substrate 116 to the substrate support 110 when depositing metal materials on the substrate 116. Additionally, the process kit 124 facilitates deposition on warped substrates without the use of edge clamps to flatten the substrate, thus advantageously facilitating edge-to-edge deposition on the substrate as well as deposition along the outer edge of the substrate, which is desirable in certain applications, for example, to prevent delamination of the deposited metal layer. The inventors have further observed that deposition uniformity near the edges on warped substrates is also improved using the apparatus disclosed herein. Moreover, by limiting or preventing material deposition on the substrate support 110, the apparatus of the present disclosure further advantageously extends tool uptime by lengthening the processing time before preventative maintenance is needed to replace the process kit.

The dielectric plate 206 has a shape that corresponds to the shape of the support surface 202 of the substrate support (e.g., the dielectric plate can be circular for a circular support surface, rectangular for a rectangular support surface, or the like). The dielectric plate 206 has a lower surface configured to cover the support surface 202 of the substrate support 110 and an upper surface configured to support the substrate 116. For example, the lower surface of the dielectric plate 206 has dimensions substantially similar to dimensions of the support surface 202 of the substrate support 110. In some embodiments, the upper surface of the dielectric plate 206 has dimensions substantially similar to dimensions of the support surface 202 of the substrate support 110. In some embodiments, the dielectric plate 206 has no through holes. In some embodiments, the dielectric plate 206 has only through holes configured to allow lift pins from the substrate support 110 to pass therethrough to facilitate raising and lowering of the substrate 116 with respect to the upper surface of the dielectric plate 206.

The dielectric deposition ring 208 has a central opening sized such that the dielectric deposition ring 208 surrounds the dielectric plate 206. As used herein, the term ring is intended to include circular and non-circular (e.g., polygonal) shapes that surround the dielectric plate 206. For example, the shape of the central opening may be the same as the shape of the dielectric plate 206. The dielectric deposition ring 208 is configured to cover a portion of the substrate support 110 disposed radially outward of the support surface 202 (e.g., the outer ledge 204).

The dielectric deposition ring 208 includes one or more fins 210 (a plurality of fins 210 illustratively shown in FIGS. 2-7) extending from an upper surface of the dielectric deposition ring 208. The one or more fins 210 advantageously increase an amount of material that can be captured by the dielectric deposition ring 208 before preventative maintenance is needed to replace and clean the dielectric deposition ring 208. An innermost fin 214 of the one or more fins 210 may be disposed along an edge of the central opening of the dielectric deposition ring 208. In some embodiments, the innermost fin 214 of the one or more fins 210 extends to a height above the upper surface of the dielectric plate 206. The innermost fin 214 extending above the upper surface of the dielectric plate 206 advantageously limits or prevents deposition of material on the upper surface of the dielectric plate 206 during processing.

In embodiments having a plurality of fins 210, including any of the embodiments described herein, individual fins of the plurality of fins 210 can be uniformly spaced apart or can be not uniformly spaced apart. Additionally, each fin of the plurality of fins 210 can have an independent geometry as compared to the other fins of the plurality of fins 210. For example, each fin can have one or more of an independent length, width, spacing, or angle as compared to any other fin of the plurality of fins 210. Accordingly, in some embodiments, at least one fin of the plurality of fins has at least one of a different height or width than another fin of the plurality of fins. In some embodiments, each fin of the plurality of fins has a successively lower height from the innermost fin 214 to each successive fin moving in a radially outward direction. In some embodiments, the length of the fins are selected to be at least a predetermined distance from the outer edge 212 of the substrate 116 when the substrate 116 is disposed atop the process kit 124 to advantageously avoid arcing during processing. For example, in some embodiments, a distance of greater than or equal to about 5 mm exists between any fin and the outer edge 212, although other distances may be used depending upon the processing conditions.

In some embodiments, including any of the embodiments described herein, each fin of the one or more fins 210 can be disposed parallel to a vertical central axis of the process kit 124 extending normal to the dielectric deposition ring 208 (e.g., perpendicular to the general plane of the dielectric deposition ring 208). In some embodiments, including any of the embodiments described herein, and as depicted in FIG. 3, each of the one or more fins 210 can be disposed non-parallel with respect to the vertical central axis. In some embodiments, including any of the embodiments described herein, at least one fin of the one or more fins 210 is disposed non-parallel to the vertical central axis of the process kit. In some embodiments having a plurality of fins 210, including any of the embodiments described herein, each fin of the plurality of fins 210 can be disposed at the same angle (e.g., parallel to each other). In some embodiments having a plurality of fins 210, including any of the embodiments described herein, at least one fin of the plurality of fins 210 can be disposed at a different angle than at least one other fin of the plurality of fins 210 (e.g., not parallel to each other).

An inner sidewall of the dielectric deposition ring 208 defines the central opening of the dielectric deposition ring 208. In some embodiments, the innermost fin 214 of the plurality of fins 210 at least partially forms the inner sidewall (see, e.g., FIGS. 2-5). The central opening of the dielectric deposition ring 208 is generally sized to closely match the outer periphery of the dielectric plate 206. Such a configuration advantageously reduces the risk of deposition in any gap that exists between the dielectric deposition ring 208 and the dielectric plate 206.

In some embodiments, a recess can be disposed along edges of the process kit 124 adjacent separate components of the process kit 124 or the substrate support 110 to reduce or prevent material deposition forming a continuous layer across the adjacent components. For example, as depicted in FIGS. 2-4, in some embodiments, a recess 216 can be disposed along a lower outer edge of the dielectric plate 206 (e.g., in the lower surface of the dielectric plate 206 adjacent the support surface 202 of the substrate support 110). Alternatively or in combination, and as depicted in FIGS. 2-4, a recess 218 can be disposed along a lower inner edge of the dielectric deposition ring 208 (e.g., in the lower surface of the dielectric deposition ring 208 adjacent the outer ledge 204 of the substrate support 110). In some embodiments, and as depicted in FIG. 4, a similar recess 402 can be formed along the outer, lower edge of the dielectric deposition ring 208. The recess 402 can advantageously reduce or prevent material deposition from forming a continuous layer from the dielectric deposition ring 208 to the substrate support 110.

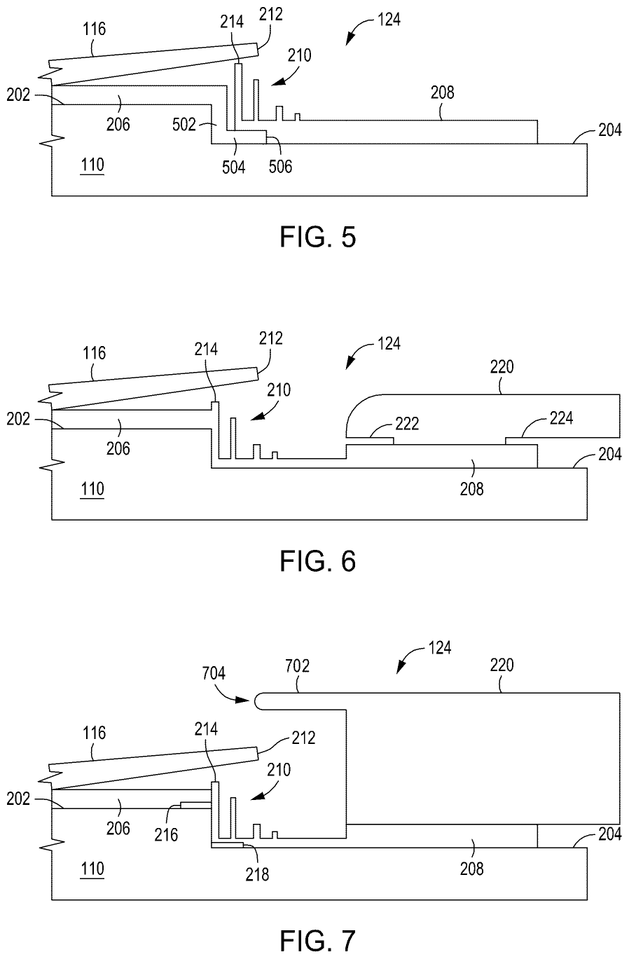

In some embodiments, and as depicted in FIG. 5, the dielectric deposition ring 208 and the dielectric plate 206 can be configured to overlap to further reduce any gaps and/or to provide a more convoluted pathway (e.g., no line of sight) between the dielectric deposition ring 208 and the dielectric plate 206. The overlap and convoluted path between the dielectric deposition ring 208 and the dielectric plate 206 further reduces the risk of deposition on the substrate support 110 in a location between the dielectric deposition ring 208 and the dielectric plate 206. For example, as shown in FIG. 5, the dielectric plate 206 further includes an outer wall 502 extending downward from the lower surface and a ledge 504 extending outwardly from a lower portion of the outer wall 502. The dielectric deposition ring 208 further includes a recess 506 disposed along a lower inner edge of the dielectric deposition ring 208. The ledge 504 is at least partially disposed within the recess 506. The innermost fin 214 of the plurality of fins 210 can be disposed in contact with the outer wall 502 or, as shown in FIG. 5, a gap can exist between the innermost fin 214 and the outer wall 502. Although not shown in FIG. 5, a recess 224 can be disposed along the lower outer edge of the dielectric deposition ring 208.

In some embodiments, and as depicted in FIG. 6, the dielectric deposition ring 208 and the dielectric plate 206 can be fabricated as a unitary or singular component (e.g., fabricated from one piece of material or fabricated from separate pieces bonded or otherwise coupled together to eliminate any gaps between the dielectric deposition ring 208 and the dielectric plate 206). Such unitary construction eliminates the risk of deposition on the substrate support 110 in a location between the dielectric deposition ring 208 and the dielectric plate 206.

In some embodiments, and as depicted in FIGS. 2, 3, 6, and 7, the process kit 124 can further include a shadow clamp 220 configured to rest atop the dielectric deposition ring 208. The shadow clamp 220 advantageously secures the dielectric deposition ring 208 (or the unitary dielectric deposition ring 208 and dielectric plate 206) to the substrate support 110 by gravity, without the need for bolts or clamps. The shadow clamp 220 further advantageously limits or prevents material deposition on the dielectric deposition ring 208 (or combination of the dielectric plate 206 and the dielectric deposition ring 208) from accumulating along the outer edge of the dielectric deposition ring 208 and shorting to the underlying substrate support 110. The shadow clamp 220 has a central opening sized larger than the dielectric plate 206 and an inner portion of the dielectric deposition ring 208. The shadow clamp 220 has a lower surface configured to rest on an outer portion of the dielectric deposition ring 208. In some embodiments, the shadow clamp 220 has a width such that an outer edge of the shadow clamp 220 extends beyond an outer edge of the dielectric deposition ring 208. In some embodiments, the shadow clamp 220 includes a recess 222 disposed along a lower inner edge of the shadow clamp 220. In some embodiments, the shadow clamp 220 further includes a recess 224 disposed along a lower outer edge of the shadow clamp 220 between the shadow clamp 220 and the dielectric deposition ring 208. Although not shown in FIG. 5, the shadow clamp 220 can also be provided in such embodiments.

In some embodiments, and as depicted in FIGS. 2, 3, and 6, a radially inner upper edge 226 of the shadow clamp 220 can be rounded to reduce or prevent any arcing during processing that might otherwise occur if a sharper edge were provided. In some embodiments, including any of the embodiments disclosed herein and as illustratively depicted in FIG. 7, the shadow clamp 220 can include an inwardly extending lip 702. The inwardly extending lip 702 can define an innermost diameter or dimension of the shadow clamp 220 to be less than a corresponding diameter or dimension of the substrate 116. The inwardly extending lip 702 is generally sufficiently spaced apart from the outer edge 212 of the substrate 116 (e.g., disposed above and as measured by the shortest straight-line distance between any edge of the inwardly extending lip 702 and the outer edge 212 of the substrate 116) to minimize or prevent arcing during processing. The inwardly extending lip 702 can also include a rounded innermost edge 704 to reduce or prevent arcing during processing. In general, the configuration of the shadow clamp 220 with respect to the dielectric deposition ring 208 and substrate 116 can be selected to minimize material build-up on the dielectric deposition ring 208.

The process kit 124 is configured to completely or substantially completely cover at least upper surfaces of the substrate support 110 (e.g., the support surface 202 and the outer ledge 204). In some embodiments, the dielectric plate 206 and the dielectric deposition ring 208 together completely or substantially completely cover at least upper surfaces of the substrate support 110. In some embodiments, the dielectric plate 206, the dielectric deposition ring 208, and the shadow clamp together completely or substantially completely cover at least upper surfaces of the substrate support 110.

In some embodiments, upper surfaces of one or both of the dielectric deposition ring 208 or the shadow clamp 220 can be textured to increase surface roughness to enhance adhesion of materials to the dielectric deposition ring 208 and/or the shadow clamp 220. The selected surface roughness can be achieved by suitable texturizing or coating techniques such as bead blasting, plasma spray coating, or the like.

While the foregoing is directed to embodiments of the present disclosure, other and further embodiments of the disclosure may be devised without departing from the basic scope thereof.

1. A process kit for a substrate support, comprising:
a dielectric plate having a lower surface configured to cover a support surface of the substrate support and an upper surface configured to support a substrate; and
a dielectric deposition ring surrounding the dielectric plate and configured to cover a portion of the substrate support disposed radially outward of the support surface.

2. The process kit of claim 1, wherein the dielectric deposition ring further comprises:
a plurality of fins extending from an upper surface of the dielectric deposition ring.

3. The process kit of claim 2, wherein an innermost fin of the plurality of fins extends to a height above an upper surface of the dielectric plate.

4. The process kit of claim 2, wherein at least one fin of the plurality of fins has at least one of a different height or width than another fin of the plurality of fins.

5. The process kit of claim 2, wherein, in a direction moving radially outward, each fin of the plurality of fins has a successively lower height.

6. The process kit of claim 2, wherein fins of the plurality of fins are not uniformly spaced apart.

7. The process kit of claim 2, wherein at least one fin of the plurality of fins is disposed non-parallel to a vertical central axis of the process kit.

8. The process kit of claim 1, further comprising at least one of:
a recess disposed along a lower outer edge of the dielectric plate; or
a recess disposed along a lower inner edge of the dielectric deposition ring.

9. The process kit of claim 1, further comprising:
a shadow clamp having a central opening sized larger than the dielectric plate and an inner portion of the dielectric deposition ring, the shadow clamp having a lower surface configured to rest on an outer portion of the dielectric deposition ring, the shadow clamp further having a width such that an outer edge of the shadow clamp extends beyond an outer edge of the dielectric deposition ring.

10. The process kit of claim 9, further comprising:
a recess disposed along a lower inner edge of the shadow clamp.

11. The process kit of claim 1, wherein the dielectric plate further comprises an outer wall extending downward from the lower surface and a ledge extending outwardly from a lower portion of the outer wall, wherein the dielectric deposition ring further comprises a recess disposed along a lower inner edge of the dielectric deposition ring, and wherein the ledge is at least partially disposed within the recess.

12. The process kit of claim 1, wherein the dielectric plate and the dielectric deposition ring are a singular component.

13. Apparatus for processing a substrate, comprising:
a substrate support having a support surface and an outer ledge disposed outward of the support surface, wherein the support surface is elevated with respect to the outer ledge; and
a process kit disposed atop the substrate support, the process kit comprising:
a dielectric plate having a lower surface covering the support surface and an upper surface configured to support a substrate; and
a dielectric deposition ring surrounding the dielectric plate and covering the outer ledge.

14. The substrate support of claim 13, wherein the dielectric deposition ring further comprises a plurality of fins extending from an upper surface of the dielectric deposition ring, and wherein at least one of:
an innermost fin of the plurality of fins extends to a height above an upper surface of the dielectric plate;
at least one fin of the plurality of fins has at least one of a different height or width than another fin of the plurality of fins;
in a direction moving radially outward, each fin of the plurality of fins has a successively lower height;
fins of the plurality of fins are not uniformly spaced apart; or
at least one fin of the plurality of fins is disposed non-parallel to a vertical central axis of the process kit.

15. The substrate support of claim 13, further comprising at least one of:
a recess disposed along a lower outer edge of the dielectric plate; or
a recess disposed along a lower inner edge of the dielectric deposition ring.

16. The substrate support of claim 13, further comprising:
a shadow clamp having a central opening sized larger than the dielectric plate and an inner portion of the dielectric deposition ring, the shadow clamp having a lower surface configured to rest on an outer portion of the dielectric deposition ring, the shadow clamp further having a width such that an outer edge of the shadow clamp extends beyond an outer edge of the dielectric deposition ring.

17. The substrate support of claim 16, further comprising:
a recess disposed along a lower inner edge of the shadow clamp.

18. The substrate support of claim 13, wherein the dielectric plate further comprises an outer wall extending downward from the lower surface and a ledge extending outwardly from a lower portion of the outer wall, wherein the dielectric deposition ring further comprises a recess disposed along a lower inner edge of the dielectric deposition ring, and wherein the ledge is at least partially disposed within the recess.

19. The substrate support of claim 13, wherein the dielectric plate and the dielectric deposition ring are a singular component.

20. A physical vapor deposition chamber, comprising:
chamber body;
a lid assembly coupled to the chamber body and configured to support one or more targets for depositing one or more materials onto a substrate during use;
a substrate support disposed within the chamber body opposite the lid assembly, the substrate support having a support surface and an outer ledge disposed outward of the support surface, wherein the support surface is elevated with respect to the outer ledge; and
a process kit disposed atop the substrate support, the process kit comprising:
a dielectric plate having a lower surface covering the support surface and an upper surface configured to support a substrate; and
a dielectric deposition ring surrounding the dielectric plate and covering the outer ledge.
